(19) United States
(12) Patent Application Publication
(10) Pub. No.: US 2025/0300120 A1
(43) Pub. Date: Sep. 25, 2025

(54) Wafer Level Land Grid Array

(71) Applicant: Apple Inc., Cupertino, CA (US)

(72) Inventors: Raymundo M. Camenforte, San Jose, CA (US); Raymond Fajardo, Swindon (GB); Flynn P. Carson, Redwood City, CA (US); Jun Zhai, Cupertino, CA (US); Chien-Sheng Chang, Hsinchu City (TW)

(21) Appl. No.: 18/614,332

(22) Filed: Mar. 22, 2024

(51) Int. Cl. H01L 23/00; H01L 23/538; H01L 25/065

(52) U.S. Cl. CPC H01L 24/73; H01L 23/5386; H01L 24/13; H01L 24/14; H01L 24/16; H01L 25/0655; H01L 2224/13008; H01L 2224/13013; H01L 2224/13541; H01L 2224/1357; H01L 2224/1403; H01L 2224/14051; H01L 2224/14132; H01L 2224/14163; H01L 2224/14177; H01L 2224/16227; H01L 2224/2101; H01L 2224/2105; H01L 2224/24226; H01L 2224/73209; H01L 2924/14252; H01L 2924/1427

(57) ABSTRACT

Packages with wafer level land grid arrays are described. In an embodiment, a package includes a die and a package routing layer over the die, where the package routing layer includes a first land that spans over a first set of vias, and a second land that spans over a second set of vias, where the vias may be connected to a metal redistribution line or directly connected to die contact pad of the die.

### BACKGROUND

### Field

Embodiments described herein relate to microelectronic chip manufacture, and more particularly to wafer level processing techniques.

### BACKGROUND INFORMATION

The advent of chip scale packages (“CSPs”) in the semiconductor industry has led to the development of wafer-level chip-scale packaging (“WLCSP”) to meet the high demand for smaller, lighter, and thinner devices. A typical WLCSP process involves dicing chips on a wafer, precisely positioning the known-good chips on a “reconstituted” carrier wafer or panel, and then implementing package routing over the reconstituted wafer or panel, where the package routing may be fan-in or fan-out. In some instances, the package may be bumped with solder bumps.

### SUMMARY

Embodiments describe packages with large metal lands that form a land grid array. In an embodiment, a package includes a die and a package routing layer with multiple lands, where the multiple lands may include a first land that spans over a first set of vias, and a second land that spans over a second set of vias. In such instances, the first land and second land, as well as the first set and second set of vias, may be of different shapes and/or sizes. In an embodiment, the multiple lands may be directly connected to a contact pad of the die through the vias. In an embodiment, the multiple lands may be connected to a contact pad of the die through a metal redistribution line. In an embodiment, a system may include a power source, a first package and a second package mounted on a routing structure, where the first package modulates the flow of power between the power source and the second package.

### BRIEF DESCRIPTION OF THE DRAWINGS

FIG. 1A is a schematic cross-sectional side view illustration of an exemplary package including multiple lands connected to a die through a metal redistribution line in accordance with embodiments.

FIG. 1B is a schematic cross-sectional side view illustration of an exemplary package including multiple lands directly connected to a die through vias in accordance with embodiments.

FIG. 2 is a schematic top-down plan view illustration of an exemplary package that shows a layout of lands and underlying vias in accordance with embodiments.

FIG. 3 is a schematic cross-sectional side view illustration of an exemplary system that includes a power source and multiple packages in accordance with an embodiment.

### DETAILED DESCRIPTION

In one aspect, it has been observed that the performance demands of modern consumer devices and computing systems necessitate higher voltages and currents, which may generate excess heat within a given package. Further, it has been observed that land grid array layouts may not be well-suited to dissipate such heat or to accommodate the flow of such high currents and voltages. For example, in a 400-micron pitch design where the distance between lands (center to center) is 400 microns, the maximum size of the lands may be approximately 240 microns, where the maximum size of the underlying vias connected to the lands may be approximately 200-210 microns. It has been observed that higher currents and voltages flowing through the vias and lands and attached solder balls may exacerbate the effects of electromigration of solder into the lands, which can cause the eventual loss of connections or even failure of a circuit. Further, such relatively small vias and lands may not effectively dissipate excess heat due to their minimal surface areas.

In accordance with embodiments, a package includes a die and a package routing layer with multiple large metal lands that may form a land grid array in which the multiple lands, respectively, span over multiple sets of vias. In such instances, the multiple lands may be larger (e.g., greater surface area) than conventional lands to dissipate heat more. In addition, the larger lands have the effect of removing the restraints on via size dictated by conventional land grid array pitches so that a size of the vias located under the multiple lands may be larger than a size of conventional land grid array vias with the same pitch design to better accommodate the higher current and voltage demands of modern devices and computing systems. Furthermore, the lands may be made thicker than conventional land grid array design to aid in thermal transfer, and solder tips may be plated along with the lands rather than attaching solder balls. The larger land (e.g., copper) thickness and thinner solder can reduce the effects of electromigration due to solder diffusion into the lands with less volume of the lands being consumed during operation at high voltages.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the embodiments. In other instances, well-known semiconductor processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

The terms “over,” “to,” “between,” “spanning” and “on” as used herein may refer to a relative position of one layer with respect to other layers. One layer “over”, “spanning” or “on” another layer or bonded “to” or in “contact” with another layer may be directly in contact with the other layer or may have one or more intervening layers. One layer “between” layers may be directly in contact with the layers or may have one or more intervening layers.

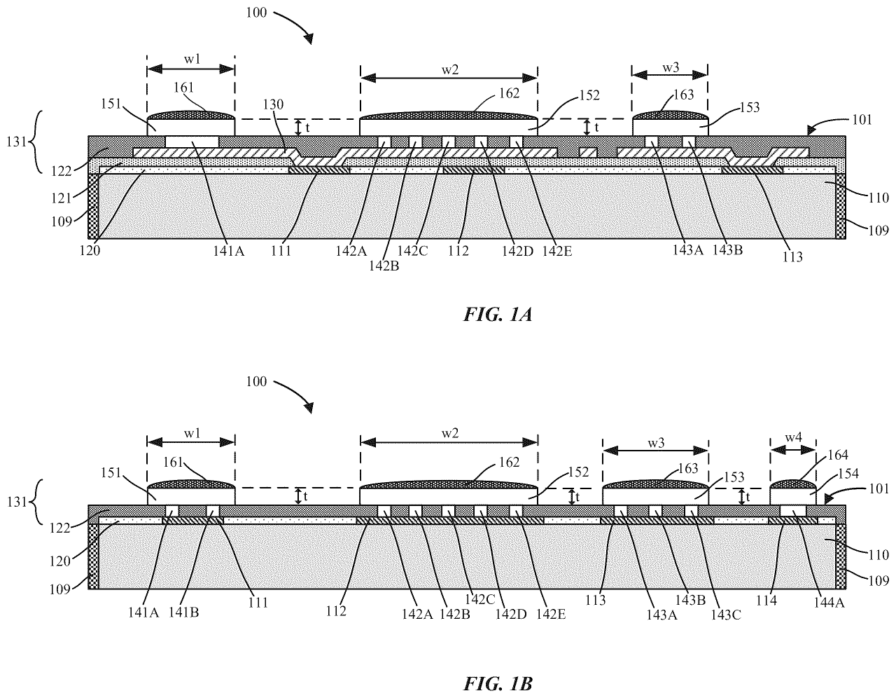

Referring now to FIG. 1A, a schematic cross-sectional side view illustration is provided of package 100 that includes multiple lands connected to a die through at least one metal redistribution line. Package 100 may include die 110 and package routing layer 131. Package 100 may be a chip-scale package (“CSP”) with an area no greater than 1.5 times that of the die area, or more specifically less than 1.2 times of the die area. However, embodiments are not so limited. Multiple dies may be included in package 100, where the package-to-die area may be greater than typical CSP criterion. Die 110 may include various types of digital, analog or mixed-signal integrated circuits. In an embodiment, die 110 may be a power management integrated circuit (“PMIC”) that may perform various functions related to power requirements (e.g., DC to DC conversion, battery charging, voltage scaling, etc.). Die 110 may include one or more die contact pads (e.g., die contact pads 111, 112, 113, etc.) to connect the internal signals from die 110 to other locations within package 100. The die contact pads may be formed as part of standard wafer fabrication processes and may be formed of metal or other suitable materials (e.g., aluminum, etc.). In addition, die 110 may also include passivation layer 120, which may be formed by standard front end of line fabrication processes (e.g., chemical vapor deposition, etc.) and may include suitable materials to hermetically seal the die (e.g., silicon nitride, etc.). Further, package 100 may also include molding compound 109 (e.g., epoxy, etc.) that surrounds a periphery of die 110. The molding compound may be formed during a reconstitution process in which dies, such as die 110, are placed onto a carrier substrate and then overmolded/embedded with a molding compound, such as molding compound 109, and further fabricated to form a reconstituted wafer or panel upon which package routing layer 131 may be subsequently formed.

In some embodiments, package routing layer 131 may include one or more metal redistribution lines, one or more dielectric layers, and multiple vias through the one or more dielectric layers. The one or more metal redistribution lines may expand and/or redistribute the I/O connections of die 110 and may be formed of copper or other suitable material. The one or more dielectric layers may be formed by standard deposition techniques (e.g., spin coating, spray coating, physical vapor deposition, chemical vapor deposition, etc.) and may include suitable materials to provide features such as isolating interconnect levels, stress buffering, etc. (e.g., low temperature polyimide (“LTPI”), high temperature polyimide (“HTPI”), polybenzoxazole (“PBO”), etc.). The vias may be formed copper or other suitable material to connect the one or more metal redistribution lines to each other, or to the die contact pads or the lands. For example, as illustrated in FIG. 1A, package routing layer 131 includes one or more metal redistribution lines 130 and dielectric layers 121 and 122. In further reference to FIG. 1A, package routing layer 131 includes via 141A to connect die contact pad 111 to land 151, vias 142A, 142B, 142C, 142D and 142E to connect die contact pad 111 to land 152, and vias 143A and 143B to connect die contact pad 113 to land 153, where the one or more metal redistribution lines 130 enable such connections.

Referring now to FIG. 1B, a schematic cross-sectional side view illustration is provided of package 100 in accordance with embodiments. Unlike the example of FIG. 1A in which package 100 included one or more metal redistribution lines to enable the connections between the die contact pads and the lands, the example of FIG. 1B does not include the one or more metal redistribution lines 130. Rather, in the example of FIG. 1B, package routing layer 131 may include one or more dielectric layers and multiple vias through the one or more dielectric layers that directly connect the die contact pads and the lands without the use of the one or more metal redistribution lines. In reference to FIG. 1B, package routing layer 131 includes vias 141A and 141B to directly connect die contact pad 111 to land 151, vias 142A, 142B, 142C, 142D and 142E to directly connect die contact pad 112 to land 152, vias 143A, 143B, and 143C to directly connect die contact pad 113 to land 153, and via 144A to directly connect die contact pad 114 to land 154, where the vias are formed through dielectric layer 122 to enable such connections.

In both FIGS. 1A and 1B, package routing layer 131 may also include multiple lands that can make up a land grid array on top surface 101. The multiple lands may span over multiple sets of vias, where the vias may be formed to a particular size, shape, and number of vias. For example, the number of vias spanned by each land may vary from land to land. In one example, a land may span over a single via, such as land 151 that spans over via 141A in FIG. 1A, or land 154 that spans over via 144A in FIG. 1B. In another example, a land may span over multiple vias, such as land 152 that spans over vias 142A, 142B, 142C, 142D, 142E in FIG. 1A. In addition, the vias may be formed to take any shape, which may include circular, oblong or rectangular via shapes, as well as other via shapes including elongated variants of such shapes. Also, the size of the vias may be larger than the size of conventional vias for the same pitch design. For example, where a conventional 400-micron pitch design may yield a maximum via size of approximately 200-210 microns, the vias described in accordance with embodiments may be greater than 200-210 microns for the same pitch design. In this way, the larger vias described in accordance with embodiments may lessen the effects of electromigration by better accommodating the flow of high currents and voltages more effectively than conventional vias with the same pitch design.

In further reference to FIGS. 1A and 1B, the lands may be formed of a metal (e.g., copper), a combination of metals (e.g., copper and platinum, etc.) or other suitable materials for enabling an electrical connection between die 110 and another device or system (e.g., main logic board, etc.), and for dissipating heat generated by the flow of current or voltage through package 100. In an embodiment, the lands are formed of copper. In addition, the lands may be formed by electroplating or other suitable methods for depositing a metal coating on top surface 101 of package 100 including the exposed vias that may be “filled” during electroplating. The lands may also be structured to form any shape or dimension (e.g., square, rectangular, triangular, circular, etc.) in order to cover or span any number or arrangement of vias, where the shape or dimension of each land may vary within the same grid array. For example, the dimensions of a particular land may be different than the dimensions of another land within the same grid array on top surface 101 of package 100 based on the performance requirements of each land, where lands designed for one purpose (e.g., supplying power) may be larger than lands designed for another purpose (e.g., transmitting data). In the example of FIG. 1A, the width, w1, of land 151 may be less than the width, w2, of land 152, but more than the width, w3, of land 153. In the example of FIG. 1B, the width, w2, of land 152 may be greater than the width, w3, of land 153, which may be greater than the width, w4, of land 154. In addition, the lands may be structured to form any thickness based on the desired thermal requirements and/or size constraints of package 100. In an embodiment, the thickness of the lands, t, may be in the range of 10-30 microns, although other thicknesses are contemplated. Further, the lands may include solder tips, where the solder tips may be electroplated onto the lands and may be formed of suitable electrically conductive material (e.g., gold-tin solder, etc.). In the example of both FIG. 1A and FIG. 1B, solder tip 161 may be electroplated on land 151, solder tip 162 may be electroplated on land 152, and solder tip 163 may electroplated on land 153. Additionally, in the example of FIG. 1B, solder tip 164 may electroplated on land 154. In this way, the lands in accordance with embodiments can have a larger volume and surface area to dissipate heat more effectively than conventional lands. Furthermore, plating of the solder tips as opposed to solder ball attachment facilitates the use of thinner solder with thicker lands to mitigate the amount of solder diffusion into the lands during operation at high voltages and the detrimental effects of electromigration on bump quality.

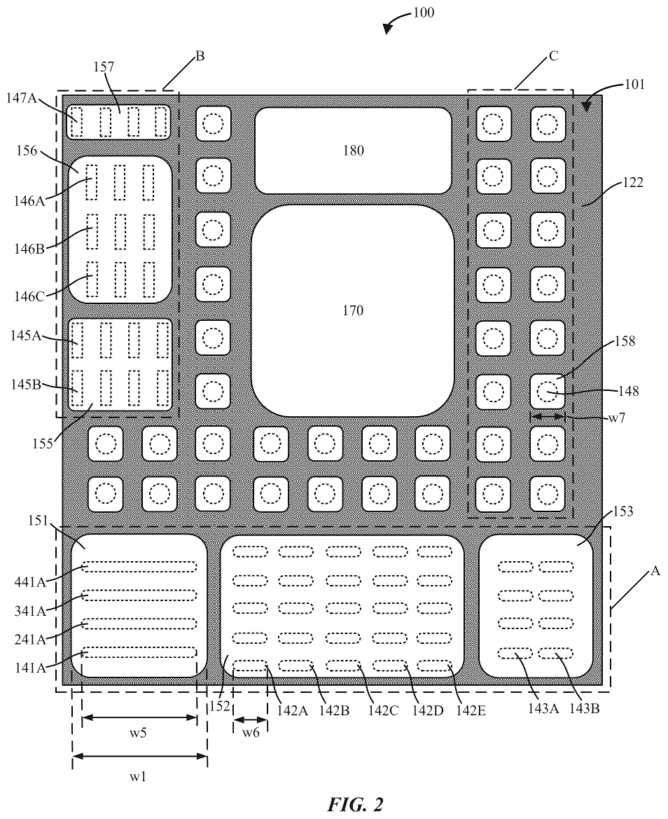

Referring now to FIG. 2, a schematic top-down plan view illustration is provided of package 100 that shows the layout of the lands and their underlying vias. It should be noted that FIG. 2 shows the multiple lands after land formation but before electroplating of the solder tips. In one aspect, package 100 may include any size, shape, or number of vias. For example, in FIG. 2, the vias may be oblong (e.g., via 141A), rectangular (e.g., via 145A), or circular (e.g., via 148), although other via shapes (including elongated variants of such shapes) are contemplated. In addition, the vias may have different sizes. For example, via 141A has a width, w5, and via 142A has a width, w6, where w5 is greater than w6. Further, the number of vias may vary from land to land. For example, a land may have a singular via, such as via 148 of land 158, or a land may have multiple vias, such as vias 141A, 241A, 341A, 441A of land 151. In another aspect, package 100 may include any size, shape or number of lands. For example, in FIG. 2, the lands may be square (e.g., land 151) or rectangular (e.g., land 152), although other land shapes are contemplated. In addition, the lands may include smaller lands with a singular via, such as land 158, or larger lands with multiple vias, such as land 152. Further, the edges of each land may vary and may include rounded corners, chamfered corners, or other types of edges.

In further reference to FIG. 2, the arrangement of lands within an array may be specifically designed to address the electrical and thermal loads of a particular package. For example, some areas of a package may experience higher temperatures or thermal loads than other sections during operation, and, for those areas that experience higher thermal loads, lands may be enlarged and/or grouped together to more effectively dissipate the excess heat. For example, in FIG. 2, areas A and B of package 100 may experience higher thermal loads than area C of package 100. In such instances, areas A and B may include larger lands, such as lands 151, 152 and 153 in area A, or lands 155, 156 and 157 in area B, as opposed to the smaller lands in area C, such as land 158. In particular, the width of square-shaped land 151, for example, is w1, where the width of square-shaped land 158, for example, is w7, where w1 is greater than w7, so that land 151 has a greater surface area than land 158. In this way, the larger surface area of the lands in areas A and B act to dissipate heat more effectively in these higher temperature areas.

In further reference to FIG. 2, package 100 may also include lands dedicated to a particular purpose. In one embodiment, package 100 may include a ground land or pad, where the grounds in the circuit (e.g., V_{SS}, etc.) may be grouped to a central location so that the ground land may act as a thermal pad for package 100. In the example of FIG. 2, package 100 includes ground land 170, which may act as a ground land or pad where the grounds of package 100 may be centrally grouped. In another embodiment, package 100 may include a power land or pad, where the current or voltage wires/traces in the circuit (e.g., V_{DD}, etc.) may be grouped to a particular land, such as land 180 in FIG. 2. Further, in some embodiments where die 110 may be a power management integrated circuit (“PMIC”) die, the larger lands may connect to other electronic circuits or electromechanical devices that convert a source of direct current from one voltage level to another. In one example, the lands may connect to one or more voltage converters or buck converters to decrease voltage, while increasing current, from its input (supply) to its output (load), which may provide greater power efficiency for the operation of package 100 as well as the other devices or systems associated with package 100.

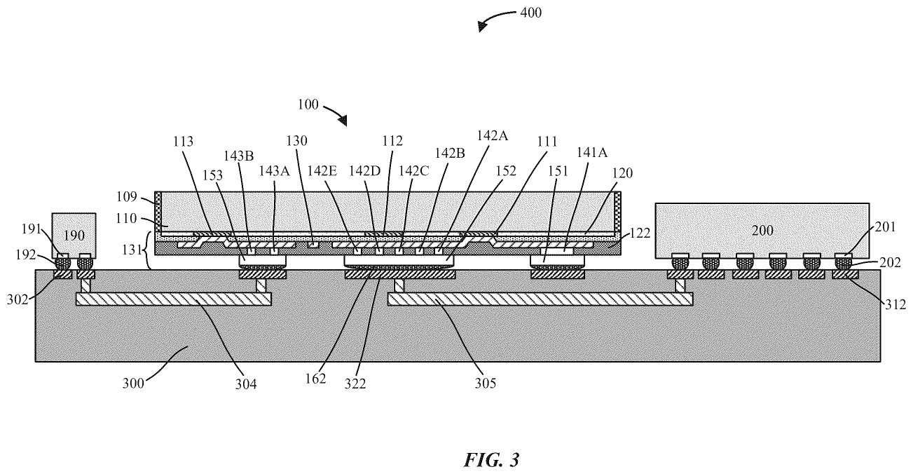

Referring now to FIG. 3, a schematic cross-sectional side view illustration is provided of a system that includes a power source and multiple packages in accordance with embodiments. System 400 may be a multi-chip module that may include a power source (e.g., voltage source), a power management chip or unit (e.g., PMIC, etc.), and an additional chip or die (e.g., system-on-chip, logic chip, etc.), where the power management chip modulates the flow and direction of electrical power between the power source and the additional chip or die. In the example of FIG. 3, system 400 includes a power source 190 (e.g., voltage source, etc.), package 100 (e.g., PMIC, etc.), and package 200 (e.g., system-on-chip, etc.) mounted to routing structure 300 (e.g., printed circuit board, interposer, etc.). Further, power source 190 may include bond pads and solder balls that connect to routing structure 300, such as bond pad 191 and solder ball 192 that connect to bond pad 302 of routing structure 300. Package 200 may also include bond pads and solder balls that connect to routing structure 300, such as bond pad 201 and solder ball 202 that connect to bond pad 312 of routing structure 300. Package 100 illustrated in FIG. 3 may be similar to the embodiment of package 100 described in FIG. 1A, where package 100 may be “flipped” and mounted to routing structure 300. In the example of FIG. 3, package 100 may include lands and solder tips that connect to routing structure 300, such as land 152 and solder tip 162 that connect to bond pad 322 of routing structure 300. Further, routing structure 300 may include metal traces, such as metal traces 304, 305, that electrically connect the components of system 400 so that package 100 may moderate the flow and direction of power between power source 190 and package 200. In such instances, the size of the lands of package 100 may be larger than the size of the lands of other components in system 400. For example, land 152 of package 100 (e.g., PMIC) may be larger than bond pad 201 of package 200 (e.g., system-on-chip), where the lands that connect to the power-related circuitry of package 100 (e.g., V_{SS} of land 170, V_{DD} of land 180, etc.) may be larger than the lands that connect to the data-related circuitry of package 200 (e.g., signal lines).

In utilizing the various aspects of the embodiments, it would become apparent to one skilled in the art that combinations or variations of the above embodiments are possible for forming a wafer level land grid array. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration.

What is claimed is:

1. A package comprising:
a die; and
a package routing layer over the die, wherein the package routing layer includes at least one metal redistribution line, lands, and vias that connect the at least one metal redistribution line to the lands;
wherein the lands include at least a first land that spans over a first set of vias, and a second land that spans over a second set of vias.

2. The package of claim 1, wherein a first surface area of the first land is different from a second surface area of the second land.

3. The package of claim 1, wherein the first set of vias have a first width, and the second set of vias have a second width, the first width being different than the second width.

4. The package of claim 1, wherein a first number of vias in the first set of vias is different from a second number of vias in the second set of vias.

5. The package of claim 1, wherein the vias include circular, rectangular or oblong vias.

6. The package of claim 1, further comprising a voltage converter connected to a third land.

7. The package of claim 6, wherein the third land connected to the voltage converter has a surface area greater than a land not connected to the voltage converter.

8. The package of claim 1, wherein the lands further include a fourth land, the fourth land being a ground land centrally located to group multiple grounds of the package.

9. A package comprising:
a die; and
a package routing layer over the die, wherein the package routing layer includes lands and vias that that connect directly to the die;
wherein the lands include at least a first land that spans over a first set of vias, and a second land that spans over a second set of vias.

10. The package of claim 9, wherein a first surface area of the first land is different from a second surface area of the second land.

11. The package of claim 9, wherein the first set of vias have a first width, and the second set of vias have a second width, the first width being different than the second width.

12. The package of claim 9, wherein a first number of vias in the first set of vias is different from a second number of vias in the second set of vias.

13. The package of claim 9, wherein the vias include circular, rectangular or oblong vias.

14. The package of claim 9, further comprising a voltage converter connected to a third land.

15. The package of claim 14, wherein the third land connected to the voltage converter has a surface area greater than a land not connected to the voltage converter.

16. The package of claim 9, wherein the lands further include a fourth land, the fourth land being a ground land centrally located to group multiple grounds of the package.

17. A system comprising:
a routing structure;
a power supply mounted to the routing structure;
a first package mounted to the routing structure, the first package including:
a die; and
a package routing layer over the die, wherein the package routing layer includes lands and vias that connect to the die;
wherein the lands include at least a first land that spans over a first set of vias, and a second land that spans over a second set of vias; and
a second package mounted to the routing structure, wherein the first package connects the power supply to the second package.

18. The system of claim 17, wherein the routing structure includes at least a first metal trace to connect the power supply to the first package, and a second metal trace to connect the first package to the second package.

19. The system of claim 17, wherein the first package is a power management unit.

20. The system of claim 17, wherein a first surface area of the first land is different from a second surface area of the second land.
